(19) United States
(12) Patent Application Publication
(10) Pub. No.: US 2019/0006544 A1
(43) Pub. Date: Jan. 3, 2019

(54) SOLAR CELL MODULE

(71) Applicant: KANEKA CORPORATION, Osaka (JP)

(72) Inventors: Toru Terashita, Osaka (JP); Gensuke Koizumi, Osaka (JP); Daisuke Adachi, Osaka (JP)

(73) Assignee: KANEKA CORPORATION, Osaka (JP)

(21) Appl. No.: 16/126,682

(22) Filed: Sep. 10, 2018

Related U.S. Application Data
(63) Continuation of application No. PCT/JP2017/002167, filed on Jan. 23, 2017.

(30) Foreign Application Priority Data
Mar. 10, 2016 (JP) 2016-046978

(51) Int. Cl. H01L 31/049; H01L 31/0465; H01L 31/054; H01L 31/02; H01L 31/0224

(52) U.S. Cl. CPC H01L 31/049; H01L 31/0465; H01L 31/022425; H01L 31/0201; H01L 31/054

(57) ABSTRACT

A solar cell module includes a solar cell string comprising a plurality of solar cells, a light-receiving-surface protective member disposed on a light receiving surface side of the solar cell string, a back-surface protective member disposed on a back surface side of the solar cell string, and a plurality of metal films. Each of the solar cells includes a photoelectric conversion part, a patterned light-receiving-surface metal electrode provided on a light receiving surface of the photoelectric conversion part, and a patterned back-surface metal electrode provided on a back surface of the photoelectric conversion part. Each of the metal films is provided between the photoelectric conversion part of the solar cell and the back-surface protective member, forming a cell exposed region on a peripheral edge of a back surface of the solar cell.

### TECHNICAL FIELD

One or more embodiments of the present invention relate to a solar cell module having excellent light utilization efficiency.

### BACKGROUND

A crystalline solar cell using a crystal semiconductor substrate such as a single crystal silicon substrate or a polycrystalline silicon substrate has a patterned metal electrode on a light receiving surface side. In a bifacial light incident type solar cell, the patterned metal electrode is also provided on a back surface side. In a monofacial light incident type solar cell, in order to effectively utilize light that has reached the back surface without being absorbed by the semiconductor substrate, a light reflective metal electrode is generally provided on the entire back surface side of the cell. Particularly, when a crystal semiconductor substrate having a small thickness is used from the viewpoint of cost reduction and the like, providing a planar metal electrode on the back surface side is effective since an amount of light reaching the back surface of the cell without being absorbed by the semiconductor substrate is large.

Since the crystalline solar cell has a small area of one cell, there is practically used a solar cell string that has a plurality of cells electrically interconnected via a wiring member and is modularized by encapsulating into between a glass plate on the light receiving surface side and a back sheet on the back surface side. In solar cell strings, a gap of approximately 2 to 4 mm is generally provided between cells provided adjacently. By reflecting the light irradiated to this gap and making it incident on the cell, to contribute to power generation, the module conversion efficiency can be improved.

In order to effectively utilize light irradiated to the gap between cells, a light scattering reflective back sheet is used in a monofacial light incident type solar cell module. Patent Literature 1 and Patent Literature 2 propose a method for increasing an incident amount of reflected light from the light receiving surface side or the back surface side of the cell, by providing a reflective material having an uneven shape at a position corresponding to the gap between cells and controlling a reflection direction of light.

### PATENT LITERATURE

### Patent Literature 1: JP 2002-43600 A

### Patent Literature 2: JP 2010-287688 A

As described in Patent Literature 1, in a monofacial light incident type solar cell module using a cell provided with a metal electrode on the entire back surface side, even when reflected light from the back sheet side strikes the back surface of the cell, it does not contribute to power generation. Therefore, it is necessary to adjust an angle of the reflected light such that the reflected light from the back sheet side is reflected again by a glass plate on the light receiving surface side and enters the cell from the light receiving surface side. However, even by adjusting a shape or an angle of unevenness of the reflective material provided on the back sheet, it is not possible to completely eliminate the reflection of light to the back surface of the cell.

In a bifacial light incident type solar cell module, a transparent back sheet is used in order to utilize light from the back surface side. As described above, providing the reflective material at a position corresponding to the gap between the cells allows refection and effective utilization of the light irradiated to the gap between the cells from the light receiving surface (front surface) side. In the bifacial light incident type solar cell module, since the metal electrode on the back surface side of the cell is in the form of a grid, the light reflected on the back sheet side and striking the back surface side of the cell can also be used effectively. However, since the back sheet in a region disposed with the cell is transparent, the light incident on the cell from the light receiving surface side to reach the back surface of the module without being absorbed by the semiconductor substrate is transmitted through the back sheet and dissipated outside the module.

A part of the reflected light from the back sheet to the back surface of the cell in the monofacial light incident type module, and a part of the light transmitted through the back sheet in the bifacial light incident type module are repeatedly reflected and scattered to enter the cell. However, loss occurs in this process. Therefore, an amount of light incident on the cell is small, and there is room for improvement in enhancing light utilization efficiency. In view of the above, one or more embodiments of the present invention provide a solar cell module enabling effective incidence on the cell, of both the light irradiated to the gap between the cells and the light transmitted through the cell and reaching the back surface side, and having high light utilization efficiency.

### SUMMARY

The solar cell module according to one or more embodiments of the present invention includes a solar cell string in which a plurality of solar cells arranged apart from each other are interconnected via a wiring member, a light-receiving-surface protective member disposed on a light receiving surface side of the solar cell string, and a back-surface protective member disposed on a back surface side of the solar cell string. In some embodiments, the light-receiving-surface protective member is light transmissive. In some embodiments, the back-surface protective member preferably is light reflective. Between the solar cell string and the light-receiving-surface protective member, a light-receiving-surface encapsulant is preferably disposed in one or more embodiments, while a back-surface encapsulant may be preferably disposed between the solar cell string and the back-surface protective member.

In one or more embodiments, a solar cell includes a photoelectric conversion part, a patterned light-receiving-surface metal electrode provided on a light receiving surface of the photoelectric conversion part, and a patterned back-surface metal electrode provided on a back surface of the photoelectric conversion part. On the back surface of the solar cell, a metal film is provided between the photoelectric conversion part and the back-surface protective member. On a peripheral edge of the back surface of the solar cell, there is a region (cell exposed region) provided with no metal film. At least a part of the patterned back-surface metal electrode is provided in the cell exposed region.

In one or more embodiments, it is preferable that the metal film is in contact with the photoelectric conversion part. In one or more embodiments, an area of the cell exposed region on the back surface of the solar cell is preferably about 0.05 to 0.5 times an area of a region provided with the metal film.

In one or more embodiments, it is preferable that a light reflection member is provided in a region disposed with no solar cell (a gap between adjacent solar cells) The light reflection member may have a higher reflectance than the back-surface protective member. In one or more embodiments, it is preferable that the light reflection member provided in the gap between the adjacent solar cells has an uneven structure on a surface on the light receiving surface side. A convex portion of the uneven structure may extend in parallel with a side of the solar cell arranged adjacently. When the light reflection member is disposed between the back-surface protective member and the back-surface encapsulant, contact of the light reflection member with the solar cell or a wiring member can be prevented by making a thickness of the back-surface encapsulant larger than a thickness of the light-receiving-surface encapsulant.

In some embodiments, since reflected light can be effectively utilized by disposing the metal film having a smaller area than that of the solar cell in between with the back-surface protective member on the back surface side of the solar cell, a solar cell module with high conversion efficiency can be obtained.

### BRIEF DESCRIPTION OF THE DRAWINGS

FIGS. 1A and 1B are schematic cross-sectional views of a solar cell module according to one or more embodiments of the present invention.

FIG. 2A is a plan view of a solar cell string viewed from a light receiving surface side, and FIG. 2B is a plan view of the solar cell string viewed from a back surface side.

FIG. 3 is a schematic cross-sectional view showing one form of a solar cell.

FIGS. 4A and 4B are plan views showing a patterned shape of a metal electrode.

FIGS. 5A, 5B, 5C and 5D are plan views showing a shape of a metal film.

FIGS. 6A and 6B are schematic cross-sectional views of a solar cell module of one or more embodiments of the present invention, and FIG. 6C is a plan view of the solar cell module.

FIG. 7 is a schematic perspective view showing one form of a light reflection member.

### DETAILED DESCRIPTION OF THE EMBODIMENTS

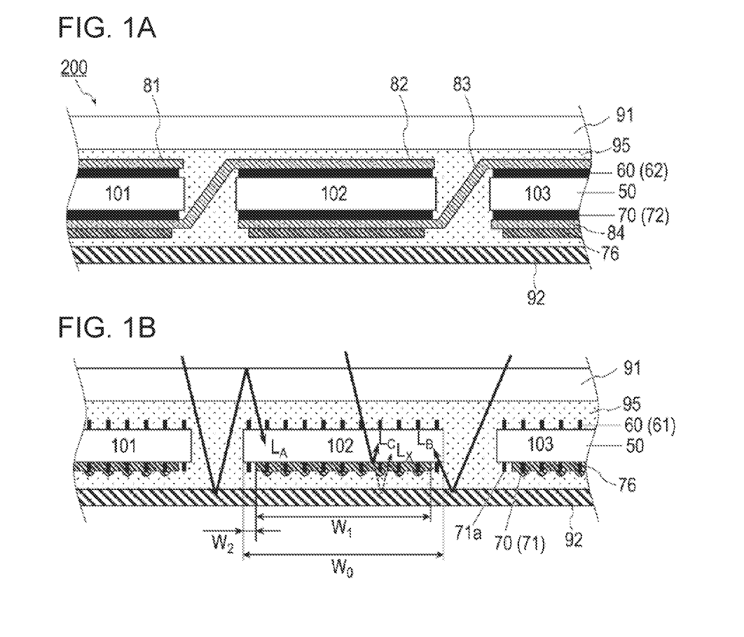

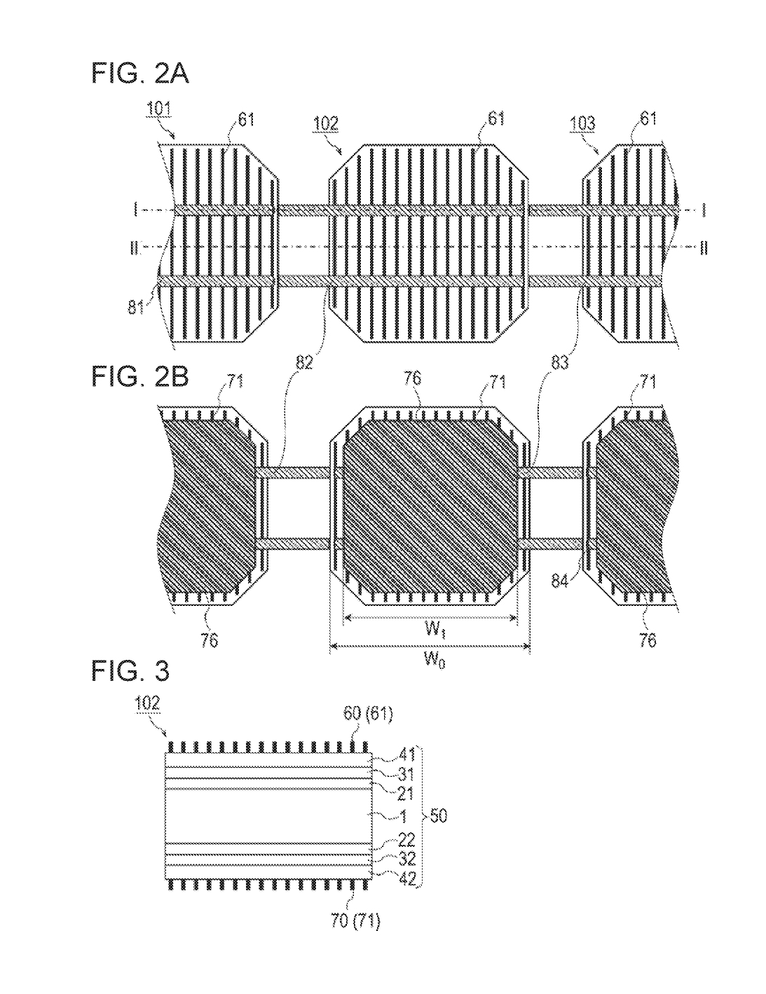

FIGS. 1A and 1B are schematic cross-sectional views of a solar cell module (hereinafter referred to as “module”) according to one or more embodiments of the present invention. A module 200 includes a plurality of solar cells 101, 102, and 103 (hereinafter referred to as “cells”). FIG. 2A is a plan view of a solar cell string viewed from a light receiving surface side, and FIG. 2B is a plan view of the solar cell string as viewed from a back surface side. FIG. 1A is a cross-sectional view taken along line I-I of FIG. 2A, and FIG. 1B is a cross-sectional view taken along line II-II of FIG. 2A.

The cell of one or more embodiments includes metal electrodes 60 and 70 on a light receiving surface side and a back surface side of a photoelectric conversion part 50, respectively. As shown in FIG. 1A, the electrodes on the front and back of adjacent cells 101, 102, and 103 are interconnected via wiring members 82 and 83, to form a solar cell string in which a plurality of cells are electrically interconnected. On a light receiving surface side (an upper side in FIGS. 1A and 1B) of the solar cell string, a light-receiving-surface protective member 91 is provided, and a back-surface protective member 92 is provided on a back surface side (a lower side in FIGS. 1A and 1B). In the module 200, the solar cell string is encapsulated by filling an encapsulant 95 between the protective members 91 and 92.

On the back surface side of the cell of one or more embodiments, a metal film 76 is disposed. In a form shown in FIGS. 1A and 2B, the metal film 76 is provided on the wiring member 84. As shown in FIG. 1B, in the region provided with no wiring member, the metal film 76 may be preferably in contact with a surface of the metal electrode 70 and the photoelectric conversion part 50.

FIG. 3 is a schematic sectional view showing one form of the cell. The photoelectric conversion part 50 includes a crystal semiconductor substrate 1. In one or more embodiments, the crystal semiconductor substrate may be a single crystal or a polycrystal, and a single crystal silicon substrate, a polycrystalline silicon substrate, or the like is used. On a surface on a light receiving surface side of the crystal semiconductor substrate 1, unevenness with a height of about 1 to 10 μm may be preferably formed. In some embodiments, forming unevenness on the light receiving surface increases a light receiving area and decreases reflectance, allowing enhancement of light confinement efficiency. A texture structure may also be provided on a back surface side of the substrate.

The cell 102 shown in FIG. 3 is a so-called heterojunction cell, including an intrinsic silicon-based thin-film 21, a first conductive silicon-based thin-film 31, and a transparent conductive film 41 that are provided in this order on a light receiving surface side of a single crystal silicon substrate 1, and including an intrinsic silicon-based thin-film 22, a second conductive silicon-based thin-film 32, and a transparent conductive film 42 that are provided in this order on a back surface side of the single crystal silicon substrate 1. In one or more embodiments, the first conductive silicon-based thin-film 31 and the second conductive silicon-based thin-film 32 have different conductivity types, one of which is p type and the other is n type.

As the intrinsic silicon-based thin-films 21 and 22 and the conductive silicon-based thin-films 31 and 32, amorphous silicon thin-films, microcrystalline silicon thin-films (thin films containing amorphous silicon and crystalline silicon), and the like are used. Among these, amorphous silicon thin-films may be preferable. In some embodiments these silicon-based thin-films can be formed by, for example, a plasma-enhanced CVD method. As p-type and n-type dopant gases at a time of forming the conductive silicon-based thin-films 31 and 32, B₂H₆ and PH₃ may be preferably used.

As the transparent conductive films 41 and 42, for example, there is used a transparent conductive metal oxide composed of indium oxide, tin oxide, zinc oxide, titanium oxide, composite oxide of these, or the like. Among these, an indium-based composite oxide containing indium oxide as a main component is preferable in some embodiments. The conductivity and reliability of the transparent conductive film can be improved by adding impurities such as Sn, Ti, W, Ce, and Ga to indium oxide.

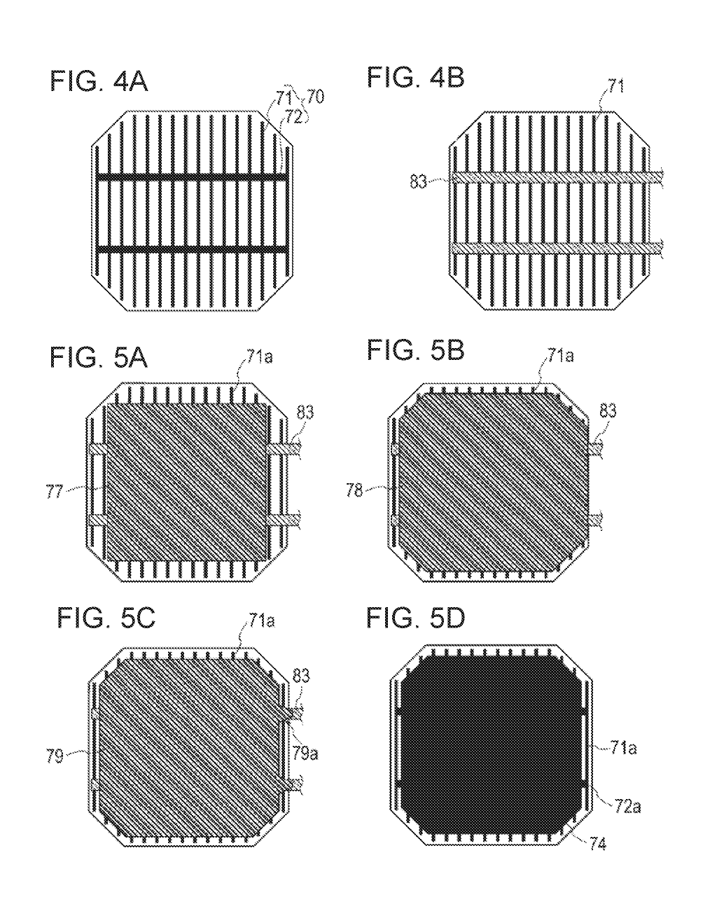

In one or more embodiments, the light-receiving-surface metal electrode 60 is provided on the transparent conductive film 41, and the back-surface metal electrode 70 is provided on the transparent conductive film 42. These metal electrodes have a predetermined pattern shape, and light can be taken in from a portion provided with no metal electrode. Although the pattern shape of the metal electrodes is not particularly limited, it may be preferable to be formed in the form of a grid formed by a plurality of finger electrodes 71 aligned in parallel, and a bus bar electrode 72 extending perpendicular to the finger electrodes, as shown in FIG. 4A. In one or more embodiments, it is preferable that the metal electrode 60 on the light receiving surface side is also similarly formed in the form of a grid. In one or more embodiments, a patterned electrode can be formed by printing a conductive paste, by a plating method, or the like. A patterned electrode formed by a printing method or a plating method can have lower electric resistance than a film-shaped electrode formed by a dry process. Therefore, carrier extraction efficiency from the cell tends to be high.

In one or more embodiments, it is preferable to set the number of the finger electrodes and the bus bar electrodes (inter-electrode distance) so as to optimize a balance between an increase of a light intake amount and a reduction of a series resistance. In FIGS. 2A, 2B, and 3, a form is illustrated in which the number of the finger electrodes on the front and back are the same, but the number of the finger electrodes may be different on the front and back. Since the light incident amount on the back surface side is smaller than that on the light receiving surface side, the number of the finger electrodes may be larger than that on the light receiving surface side, to prioritize the reduction of the series resistance. For example, it may be preferable that the number of the finger electrodes on the back surface side is set to about 2 to 3 times the number of those on the light receiving surface side.

In one or more embodiments, by interconnecting metal electrodes of adjacent cells via a wiring member, a solar cell string is formed. As the wiring member, solder-plated copper foil or the like is used. By using the wiring member having an uneven structure on the light receiving surface side (an connecting surface with the back-surface metal electrode), it is possible to scatter light incident on the wiring member and take the re-reflected light at the light-receiving-surface protective member into the cell, thereby enhancing light utilization efficiency. For connection between the metal electrode and the wiring member, a conductive adhesive, solder, or the like is used.

From the viewpoint of preventing leakage through the wiring member, in some embodiments adjacent cells are arranged apart from each other by about several millimeters. As shown in FIG. 4A, when the metal electrode is formed in the form of a grid, the wiring member 83 may be preferably connected to bus bar electrodes 62 and 72, as shown in FIGS. 1A and 4B. In the form shown in FIGS. 1A, 1B, 2A, and 2B, a plurality of cells are interconnected in series by connecting the back surface electrode of the cell 101 and the light receiving surface electrode of the cell 102 through the wiring member 82, and connecting the back surface electrode of the cell 102 and the light receiving surface electrode of the cell 103 through the wiring member 83.

As shown in FIG. 2B, on the metal electrode 70 on the back surface side, the metal film 76 is provided. The metal film 76 has a smaller area than the photoelectric conversion part 50 of the cell and is disposed at a center on the back surface side of the cell. Therefore, there is a region (cell exposed region) provided with no metal film, on a peripheral edge of the back surface side of the cell. The metal film 76 covers the finger electrode in a region (metal-film disposed region) provided with the metal film in an in-plane central portion. In the cell exposed region, a finger electrode 71a and the photoelectric conversion part 50 are exposed.

In one or more embodiments, the metal film 76 has a function of reflecting light that is incident on the cell from the light receiving surface side and transmitted to the back surface side without being absorbed by the photoelectric conversion part 50, and of making the light re-incident on the cell from the back surface side (cell-transmitted re-incident light L_{C} in FIG. 1B). Since the crystalline silicon substrate has low spectral sensitivity of long wavelength light (infrared light) in the solar spectrum, transmitted light to the back surface side of the cell is mainly infrared light. From the viewpoint of enhancing light utilization efficiency by reflection on the metal film, a material having a high reflectance to near-infrared light may be preferably used as the metal film 76. Specifically, silver, copper, aluminum, and the like can be mentioned, and among these, copper and silver may be preferable.

In one or more embodiments, the metal film 76 can be formed by cutting a metal foil such as copper foil or silver foil into a predetermined shape. From the viewpoint of resistance reduction and handleability, a thickness of the metal film may be preferably from 1 to 30 μm, more preferably from 3 to 20 μm, and still more preferably from 5 to 15 μm. The metal film having a predetermined shape may be disposed on the back surface of the cell that has already been connected with the wiring member. As will be described later, encapsulating the solar cell string with the encapsulant enables fixation of a position of the metal film disposed on the back surface of the cell. The metal film 76 does not need to be continuous in the plane, and for example, a metal film may not be provided in a connection region (a region formed with the bus bar electrode 72) of the wiring member 83.

In one or more embodiments, the metal film may be disposed between the photoelectric conversion part 50 and the back-surface metal electrode 70, and between the back-surface metal electrode 70 and the wiring member 83. Further, the metal film may be disposed between the encapsulant 95 and the back-surface protective member 92. However, from the viewpoint of reducing the resistance and increasing an intake amount of the cell-transmitted re-incident light L_{C} to be taken into the cell, the metal film may be preferably arranged to be in contact with the back-surface metal electrode 70, and may be more preferably also in contact with the photoelectric conversion part 50, in addition to the back-surface metal electrode.

By disposing the encapsulant on the light receiving surface side and the back surface side of the solar cell string including the metal film 76 on the back surface side, and encapsulating between the light-receiving-surface protective member 91 and the back-surface protective member 92, a module of one or more embodiments is obtained. As the encapsulant 95, it may be preferable to use a transparent resin such as a polyethylene resin composition containing an olefinic elastomer as a main component, polypropylene, ethylene/α-olefin copolymer, ethylene/vinyl acetate copolymer (EVA), ethylene/vinyl acetate/triallyl isocyanurate (EVAT), polyvinyl butyrate (PVB), silicon, urethane, acrylic, or epoxy. The material of the encapsulant on the light receiving surface side and the back surface side may be the same or different.

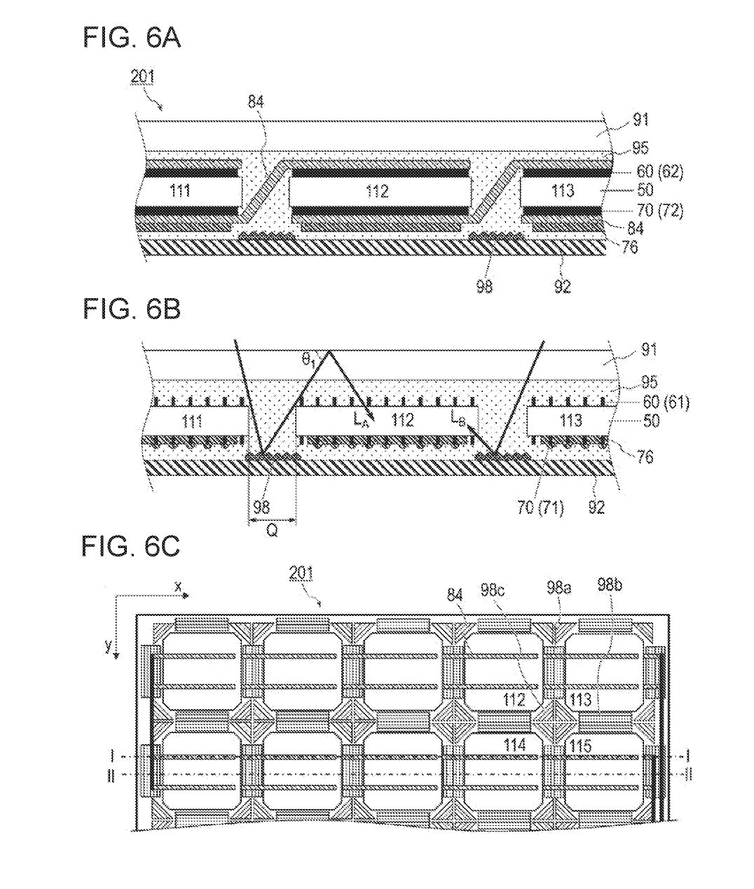

In one or more embodiments, the light-receiving-surface protective member 91 is light transmissive, and glass, transparent plastic, or the like is used. As the back-surface protective member 92, a light reflective film may be preferably used. Meanwhile, the back-surface protective member may be light transmissive, but in a case where a light transmissive back-surface protective member is used, a light reflection member may be preferably provided in a region provided with no cell as shown in FIGS. 6A to 6C. As the light-reflective back-surface protective member, those exhibiting a metallic color or white color may be preferable, and a white resin film or a laminate obtained by sandwiching a metal foil such as aluminum between resin films and the like may be preferably used.

By performing heat compression while the encapsulant and the protective member are disposed and laminated on each of the light receiving surface side and the back surface side of the solar cell string, the encapsulant also flows between the cells and to an edge of the module, to cause modularization. A pressure at the time of modularization causes the metal film 76 to deform to be in contact with the surface of the photoelectric conversion part (see FIG. 1B).

In some embodiments most of the light incident from a light receiving surface side of the module is irradiated to the cell from the light receiving surface side, but a part of the light is irradiated to a gap between adjacent cells and reaches the back surface side of the module. Further, a part of the light incident on the cell from the light receiving surface side reaches the back surface side of the cell without being absorbed by the photoelectric conversion part 50. Reflecting the light reaching the back surface and making the light re-incident on the cell enable improvement of light utilization efficiency and enhancement of the module conversion efficiency.

The module according to one or more embodiments of the present invention is provided with the metal film 76 having a smaller area than the cell on the back surface side of the cell, thereby having high light utilization efficiency. With reference to FIG. 1B, enhancement of light utilization efficiency in the module according to one or more embodiments of the present invention will be described.

In one or more embodiments, light irradiated to a gap between the cells is reflected to the light receiving surface side by the back-surface protective member 92. A part of the light reflected by the back-surface protective member 92 is again transmitted through the gap between the cells and reaches the light receiving surface side, is re-reflected at an air interface of the light-receiving-surface protective member 91, and enters the cell from the light receiving surface side (light-receiving-surface side re-incident light L_{A}).

In one or more embodiments, a part of the light irradiated to the gap between the cells and reflected by the back-surface protective member 92 reaches the back surface of the cell. Most of the reflected light reaching the back surface side of the cell from the back-surface protective member 92 reaches a peripheral region of the cell. In a monofacial light incident type cell provided with a metal electrode on the entire back surface side, light from the back surface side of the cell cannot be taken into the photoelectric conversion part. On the other hand, in the module according to one or more embodiments of the present invention, there is the cell exposed region where the metal film 76 is not provided, on the peripheral edge of the back surface of the cell. Therefore, the light reaching the back surface of the cell from the back-surface protective member 92 can be taken into the cell from the cell exposed region (back-surface side re-incident light L_{B}).

In one or more embodiments where the metal film 76 is not provided on the back surface side of the cell, the light incident on the cell from the light receiving surface side and transmitted to the back surface side without being absorbed by the photoelectric conversion part 50 is, such as light Lx shown by the dotted line in FIG. 1B, transmitted through the encapsulant 95, and then reflected by the back-surface protective member 92 to be incident on the cell from the back surface. Generally, the polymer material constituting the encapsulant is transparent to visible light, but an absorption amount of infrared ray is large. Therefore, the light Lx that is reflected by the back-surface protective member and incident on the cell tends to be absorbed by the encapsulant before being incident on the cell. In addition, optical loss due to light transmission or the like of the back-surface protective member 92 may occur. In contrast, in the module according to one or more embodiments of the present invention, disposing the high reflective metal film 76 on the back surface side of the cell allows reduction of the optical loss caused by light absorption or the like in the encapsulant, and an increase of re-incident of light transmitted through the cell (cell-transmitted re-incident light L_{C}). In particular, providing the metal film 76 in contact with the back surface side of the photoelectric conversion part 50 allows reduction of the optical loss at the interface, and further enhancement of utilization efficiency of the cell-transmitted light.

In the cell exposed region where the metal film 76 is not provided, optical loss occurs due to the cell-transmitted light reaching the back-surface protective member. However, in one or more embodiments reducing an area of the cell exposed region allows reduction of influence of loss of light transmitted through the cell exposed region. On the other hand, providing the cell exposed region causes the back-surface side re-incident light L_{B} to be taken into the cell as described above. Since the increase in the back-surface side re-incident light L_{B} due to the provision of the cell exposed region is smaller than the loss of the cell-transmitted re-incident light, light utilization efficiency as a whole can be improved.

As described above, by providing the metal film 76 on the back surface side of the cell in one or more embodiments, light (mainly infrared light) transmitted through the cell can be reflected by the metal film, to increase the intake amount of the cell-transmitted re-incident light L_{C}. By providing the cell exposed region disposed with no metal film on the peripheral edge on the back surface of the cell, the back-surface side re-incident light L_{B} derived from the reflected light from the back-surface protective member can be taken into the cell. Therefore, the module according to one or more embodiments of the present invention is excellent in light intake efficiency.

In one or more embodiments, the back-surface metal electrode is also formed in the cell exposed region at the peripheral edge of the back surface. Since the metal electrode 71a is provided in the cell exposed region, carriers at the peripheral edge of the cell can be effectively collected. Furthermore, since contact of the metal film 76 with the photoelectric conversion part 50 causes reduction of the in-plane resistance of the surface of the photoelectric conversion part, carrier transport efficiency to the back-surface metal electrode tends to be improved and the fill factor of the module tends to be improved. Particularly, in a case where the transparent conductive film 42 is provided on the surface of the photoelectric conversion part 50 as in the heterojunction cell, since contact of the transparent conductive film 42 with the metal film 76 allows smooth movement of carriers in the plane, the fill factor tends to be improved.

In one or more embodiments, the shape of the metal film 76 and the shape of the cell exposed region, and the size and area ratio of these, may be set from the viewpoint of light intake efficiency and resistance reduction. For example, a ratio W₁/W₀ of a width W₁ of the metal-film disposed region to a cell width W₀ may be preferably about 0.8 to 0.95, and more preferably about 0.83 to 0.92. Further, a width from an edge of the cell to the metal-film disposed region, that is, a width W₂ of the cell exposed region may be preferably 3 to 30 mm, and more preferably 5 to 20 mm. As the width of the cell exposed region increases, an intake amount of the back-surface side re-incident light L_{B} tends to increase and the intake amount of the cell-transmitted re-incident light L_{C} tends to decrease. As the width W₁ of the metal-film disposed region increases, an area ratio of the metal-film disposed region also increases. Therefore, the resistance on the back surface side of the cell tends to decrease and the fill factor of the module tends to be improved. A ratio (S₂/S₁) of an area S₂ of the cell exposed region to an area S₁ of the metal-film disposed region may be preferably 0.05 to 0.5, and more preferably 0.125 to 0.35.

In FIG. 2B, the metal film 76 having a similar shape to that of a semi-square type substrate is illustrated. However, in one or more embodiments the shape of the metal film may not be similar to that of the cell, and for example, a rectangular metal film 77 as shown in FIG. 5A may be used. On a side connected to the light receiving surface of the adjacent cell (a right side in FIGS. 5A to 5C), more current flows to the wiring member 83. Therefore, from the viewpoint of improving carrier transport efficiency, as shown in FIG. 5B, a metal film 78 may be arranged so as to be biased toward the side connected to the light receiving surface of the adjacent cell. In addition, as shown in FIG. 5C, there may be used a metal film 79 having a protrusion 79a in a region provided with the wiring member connected to the adjacent cell. Although the metal film is provided on the wiring member 83 in FIGS. 5A to 5C, the metal film may be disposed between the metal electrode and the wiring member.

In one or more embodiments, the metal film can also be formed using other than the metal foil. For example, the metal film may be formed by a printing method such as inkjet or screen printing, or a wet process such as a plating method, and the metal film may be formed by a dry process such as a vacuum deposition method, a sputtering method, or a CVD method. These metal films may be formed either before or after the back-surface metal electrode 70 (the finger electrode and the bus bar electrode). Further, the back-surface metal electrode and the metal film may be formed at the same time. For example, as shown in FIG. 5D, a patterned metal layer may be formed so as to have a planar region 74 corresponding to the metal-film disposed region at a central portion of the back surface of the cell, and to have patterned electrode parts 71a and 72b around the planar region 74. A thickness of the metal film formed by the wet process may be preferably 1 μm or more. A thickness of the metal film formed by the dry process may be preferably 50 nm or more, and more preferably 100 nm or more.

The module according to one or more embodiments of the present invention may be provided with a light reflection member having a higher reflectance than that of the back-surface protective member, in a region disposed with no cell. Providing the light reflection member at a position provided with no cell allows efficient reflection of light irradiated to the gap between the cells and an increase in the light-receiving-surface side re-incident light L_{A} and the back-surface side re-incident light L_{B}, and enables enhancement of light utilization efficiency.

FIGS. 6A and 6B are schematic cross-sectional views of a module provided with a light reflection member 98 on the back-surface protective member 92. FIG. 6C is a schematic plan view of the module viewed from the light receiving surface side. In FIG. 6C, illustration of the finger electrode is omitted. FIG. 6A is a cross-sectional view at a position provided with the wiring member on the bus bar electrode (a position of line I-I in FIG. 6C), while FIG. 6B is a cross-sectional view at a position provided with no wiring member (a position of line II-II in FIG. 6C). The module shown in FIGS. 6A to 6C includes the light reflection member 98 having unevenness, between the back-surface protective member 92 and the encapsulant 95 in a region Q where cells are not disposed.

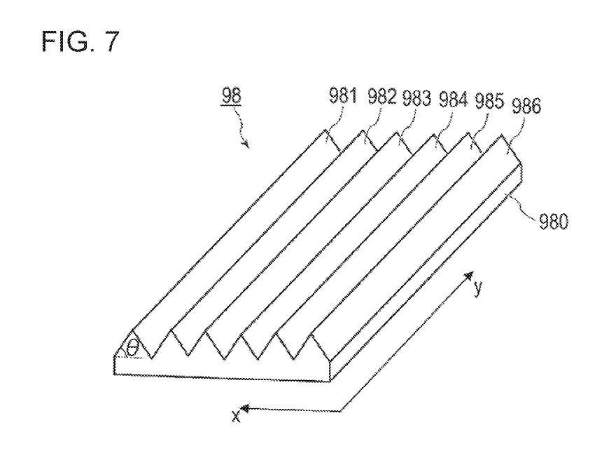

FIG. 7 is a schematic perspective view showing one form of the light reflection member having unevenness. The light reflection member in FIG. 7 includes triangular prism-shaped convex portions 981 to 986 aligned in an x-direction on a base part 980. Each convex portion extends in a y-direction. While incident light is scattered and reflected at various angles in a general light reflective back sheet such as a white resin film, reflected light is reflected in a certain direction by arranging a light reflection member provided with an uneven structure on the light receiving surface side surface. Adjusting a shape and an angle of the unevenness causes reduction of the amount of light that is reflected by the light reflection member to reach the metal-film disposed region on the back surface of the cell, and causes an increase of the back-surface side re-incident light L_{B} taken in from the cell exposed region and the light-receiving-surface side re-incident light L_{A} that is reflected by the light-receiving-surface protective member and enters the cell from the light receiving surface side.

In one or more embodiments, in accordance with an increase of an angle θ formed by the bottom surface of the light reflection member and the inclination of the convex portion, a propagation angle θ₁ of the light reflected on the light receiving surface of the module increases. As the angle θ₁ increases, the reflectance at the air interface of the light-receiving-surface protective member 91 increases. A refractive index of resin and glass is about 1.4 to 1.5, and a critical angle at the air interface is about 40°. Since total reflection occurs when the θ₁ becomes larger than the critical angle, the light-receiving-surface side re-incident light L_{A} can be further increased. On the other hand, when the inclination angle θ of the convex portion of the light reflection member is excessively large, there is a tendency that the amount of light that is reflected by the light reflection member to reach the metal-film disposed region on the back surface of the cell becomes large. Therefore, the inclination angle θ of the convex portion of the light reflection member may be preferably 200 to 450, and more preferably 25°≤θ≤40°.

From the viewpoint of controlling a reflection direction of light from the light reflection member, it may be preferable in one or more embodiments to provide the convex portions 981 to 986 extending in a predetermined direction as shown in FIG. 7. Meanwhile, the shape of the convex portion need not be the triangular shape (triangular cross section), but may be a curved shape such as a semi-cylindrical shape. A height of the convex portions of the light reflection member may be preferably about 10 to 500 μm, and more preferably about 20 to 200 μm.

As shown in FIG. 6C, in a light reflection member 98a disposed between adjacent cells 112 and 113, the convex portion of some embodiments preferably extends in the y-direction to be parallel to a side of the adjacent cell. Similarly, in a light reflection member 98b disposed between the adjacent cells 113 and 115, the convex portion of some embodiments preferably extends in the x-direction to be parallel to a side of the adjacent cell. When the side of the adjacent cell is parallel to the extending direction of the convex portion, the back-surface side re-incident light L_{B} tends to increase. In order to increase light reflected in a direction of the nearest cell, in a light reflection member 98c provided at an intersection point of gaps between the cells (a region surrounded by the cells 112, 113, 114, and 115 in FIG. 6C), the convex portion of some embodiments preferably extends to face the nearest cell.

In one or more embodiments, a width of the light reflection member may be equal to an interval between adjacent cells (a width of the region Q disposed with no cell), or may be different from the interval between the cells. From the viewpoint of enhancing utilization efficiency of reflected light, it may be preferable that the width of the light reflection member is larger than the interval between adjacent cells, and the reflecting member is disposed over the entire region where the cell is not disposed.

In one or more embodiments, when the width of the light reflection member is larger than the interval between adjacent cells, the region disposed with the light reflection member and the region disposed with the cell overlap each other. Therefore, in one or more embodiments, it is preferable to select the thickness and shape of the light reflection member, the material and thickness of the encapsulant, and the like, so as not to cause insulation failure or cell breakage due to contact between the light reflection member and the cell. For example, insulation failure and cell breakage may be prevented by increasing the thickness of the encapsulant provided between the cell and the back-surface protective member. Further, increasing the thickness of the encapsulant on the back surface side can also prevent insulation failure due to contact between the light reflection member and the wiring member. On the other hand, an increase of the thickness of the protective member is likely to cause optical loss due to light absorption of the encapsulant existing between the light-receiving-surface protective member 91 and the cell. Therefore, in one or more embodiments, it is preferable to increase the thickness of the back-surface encapsulant disposed between the cell and the back-surface protective member without changing the thickness of the light-receiving-surface encapsulant disposed between the cell and the light-receiving-surface protective member. The thickness of the back-surface protective member may be preferably, for example, 1.2 times or more the thickness of the light-receiving-surface side protective member, and more preferably 1.5 times or more.

In one or more embodiments, the light reflection member 98 may be simply placed on the back-surface protective member 92, but it may be preferable to fix the light reflection member 98 by bonding or the like to the surface of the back-surface protective member. Alternatively, there may be used a back-surface protective member with a light reflection member buried inside. In order to improve efficiency of the module production process, it may be preferable to perform encapsulating while stacking the back-surface protective member having the light reflection member fixed on the surface and the solar cell string such that the cell is arranged in a region provided with no light reflection member.

### EXAMPLES

Hereinafter, one or more embodiments of the present invention will be described in more detail by comparing examples and comparative examples, but the present invention is not limited to the following examples.

### [Production of Solar Cell]

On a light receiving surface side of a 6-inch n-type single crystal silicon substrate (semi-square type having a side length of 156 nm) with a thickness of 160 μm on which texture is formed on the front and back, an intrinsic amorphous silicon layer with a film thickness of 4 nm and a p-type amorphous silicon layer with a film thickness of 6 nm were formed by a plasma-enhanced CVD method. Thereafter, on a back surface side of the silicon substrate, an intrinsic amorphous silicon layer with a film thickness of 5 nm and an n-type amorphous silicon layer with a film thickness of 10 nm were formed by a plasma-enhanced CVD method. On each of the p layer and the n layer, an ITO layer with a film thickness of 100 nm was formed by a sputtering method. After that, according to a method described in an example of WO 2013/077038, a patterned collector electrode in the form of a grid including a finger electrode and a bus bar electrode was formed on each of the front and back ITO layers, to obtain a heterojunction solar cell. Three bus bar electrodes were provided on both of the light receiving surface and the back surface, and the number of the finger electrodes on the back surface side was set to twice the number of the finger electrodes of the light receiving surface electrode.

### Example 1

A wiring member was connected to the light receiving surface electrode and the back surface electrode of the cell via a conductive adhesive, to produce a solar cell string in which nine solar cells were interconnected in series. An interval between adjacent cells was 2 mm. As the wiring member, a diffusion tab made by coating, with silver, a surface of a copper foil having an uneven structure.

A total of 54 solar cells were interconnected in series by placing an EVA sheet on a white sheet glass as the light-receiving-surface side protective member, then arranging six rows of solar cell strings on the EVA sheet such that a distance between adjacent strings was 2 mm, and providing an electrical connection at an edge as shown in FIG. 7C. Thereafter, arranging a copper foil (thickness 10 μm) cut into a semi-square shape having a shape similar to that of the silicon substrate and having a side length of 146 mm on each of the solar cell (back surface of the cell) such that a region of 5 mm from an edge of the cell was made to be the cell exposed region. An EVA sheet as a back surface side encapsulant was placed on the copper foil, and a white light reflective back sheet provided with a white resin layer on a substrate PET film was placed as a back-surface protective member, on the EVA sheet. After performing heat compression at atmospheric pressure for 5 minutes, a solar cell module was obtained by holding at 150° C. for 60 minutes to crosslink the EVA.

### Example 2

A solar cell module was produced in the same manner as in Example 1, except that the size of the copper foil was changed such that a length of one side was 136 mm, and a region of 10 mm from the edge of the cell was made to be the cell exposed region.

### Example 3

A solar cell module was produced in the same manner as in Example 1, except that the size of the copper foil was changed such that a length of one side was 126 mm, and a region of 15 mm from the edge of the cell was made to be the cell exposed region.

### Example 4

There was used a back-surface protective member made by bonding the same diffusion tab (width 5 mm, the inclination angle θ of the convex portion θ=30°) as that used as the wiring member at the time of producing the solar cell string, on a light receiving surface side of the back sheet. The diffusion tab was located between adjacent cells in the solar cell string and between cells between adjacent solar cell strings, and arranged such that an extending direction of the convex portion was parallel to a side of the adjacent cell. A solar cell module was produced in the same manner as in Example 2, except that there was used a back sheet bonded with the diffusion tab as the light reflection member.

### Comparative Example 1

A solar cell module was produced in the same manner as in Example 1, except that the copper foil was not disposed between the solar cell and the EVA sheet on the back surface side.

### Comparative Example 2

A solar cell module was produced in the same manner as in Example 1, except that the size of the copper foil was changed such that a length of one side was 156 mm, that is, the same size as the cell, and no cell exposed region was provided.

### [Solar Cell Module Performance Measurement]

Measurement was made on conversion properties (short-circuit current (Isc), open-circuit voltage (Voc), fill factor (FF), and maximum output (Pmax)) of the solar cell modules of the above examples and comparative examples. Table 1 shows the width W₂ of the cell exposed region of each module, a ratio S₂/S₁ of an area of the cell exposed region to an area of the metal-film disposed region, the presence or absence of disposition of the light reflection member in an interval between the cells, and module characteristics. It should be noted that the module characteristics in Table 1 are shown as relative values with the characteristic 1 of the solar cell module of Comparative Example 1 taken as 1.

TABLE 1

| | | | Light | | | | |
|---|---|---|---|---|---|---|---|
| | | | reflection | | | | |
| | | | member | | | | |
| | Metal film | | between | Module characteristics | | | |
| | W₂ | S₂/S₁ | cells | I_{sc} | V_{oc} | FF | Pₘₐₓ |
| Example 1 | 5 mm | 0.14 | No | 1.003 | 1.000 | 1.006 | 1.009 |
| Example 2 | 10 mm | 0.31 | No | 1.005 | 1.000 | 1.005 | 1.010 |
| Example 3 | 15 mm | 0.53 | No | 1.000 | 1.000 | 1.003 | 1.003 |
| Example 4 | 10 mm | 0.31 | Yes | 1.015 | 1.000 | 1.005 | 1.020 |
| Comparative | — | | No | 1 | 1 | 1 | 1 |
| Example 1 | | | | | | | |
| Comparative | 0 mm | 0 | No | 0.990 | 1.000 | 1.006 | 0.996 |
| Example 2 | | | | | | | |

In comparison between Comparative Example 1 in which the metal film was not provided on the back surface and Example 2 in which the metal film was provided on the back surface such that the region 10 mm from the edge of the cell was made to be the cell exposed region, it is shown that, in Example 2, the Isc was improved by 0.5%, the FF was improved by 0.5%, and the Pmax was improved by 1% as compared with Comparative Example 1. On the other hand, in comparison between Comparative Example 1 with Comparative Example 2 in which the metal film was provided on the entire back surface of the cell, it is shown that, in Comparative Example 2, the FF was improved by 0.6% as compared with Comparative Example 1, but the Isc decreased by 1% and the Pmax decreased by 0.4%.

Improvement of the FF in Example 2 and Comparative Example 2 is considered to be resulting from reduced resistance of the back surface side of the cell by providing the metal film to be in contact with the back surface of the cell. In Examples 1 to 3 and Comparative Example 2, it is considered that the reduction in resistance due to the provision of the metal film on the back surface side contributes to the improvement of the FF, also from the fact that the FF tends to improve as the width W₂ of the cell exposed region is smaller and the area of the metal film is larger.

In Comparative Example 2, it is considered that the cell-transmitted re-incident light L_{C} is increased as compared with Comparative Example 1 by providing the metal film on the back surface of the cell. However, it is considered that the Isc has decreased because the incidence of the back-surface side re-incident light L_{B}, which is the reflected light from the back sheet, on the cell is hindered. On the other hand, in Example 2, the Isc is considered to have increased because there is the region (cell exposed region) having the width of 10 mm and provided with no metal film at the peripheral edge of the cell, so that the cell-transmitted re-incident light L_{C} is taken into the cell in the region provided with the metal film, and the back-surface side re-incident light L_{B} is incident on the cell from the cell exposed region.

Even in Example 1 in which the width W₂ of the cell exposed region was 5 mm, the Isc was improved as in Example 2 as compared with Comparative Example 1 and Comparative Example 2. On the other hand, in Example 3 in which the width W₂ of the cell exposed region was 15 mm, the FF was improved as compared with Comparative Example 1 in which no metal film was provided on the back surface of the cell, but the Isc was equivalent to Comparative Example 1. It is considered that, since most of the back-surface side re-incident light L_{B} is incident on the cell from the peripheral edge of the back surface of the cell, a significant increase in the back-surface side re-incident light L_{B} cannot be expected even by increasing the W₁ as compared with the predetermined value, but the cell-transmitted re-incident light L_{C} decreases with an increase in the W₂ (decrease in the area of the metal film). That is, it is considered that Example 3 has shown the Isc equivalent to that of Comparative Example 1 since the increase in the cell-transmitted re-incident light L_{C} due to the provision of the metal film on the back surface of the cell is substantially equal to the decrease in the back-surface side re-incident light L_{B}.

These results have shown that, while the FF tends to increase with an increase in the area of the metal film, there is an optimum value of the area of the metal film (a width of the exposed region) that maximizes the Isc due to the balance between the back-surface side re-incident light L_{B} and the cell-transmitted re-incident light L_{C}. Considering these factors, it is possible to obtain a module excellent in conversion efficiency by setting the size of the metal film to be provided on the back surface of the cell.

In Example 4 in which the light reflection member was provided at a position corresponding to the gap between adjacent cells, the Isc was further improved by 1% as compared with Example 2. This is considered to be resulting from that, since the convex portion of the light reflection member has an inclination, an angle of the light reflected on the light receiving surface of the module becomes constant, and the light reflection at the glass-air interface has increased to increase the light-receiving-surface side re-incident light L_{A}, in addition to the increase in the back-surface re-incident light L_{B} to the exposed region as the light incident on the gap between the cells is specularly reflected by the surface of the light reflection member.

### REFERENCE SIGNS LIST

200, 201 solar cell module
101 to 103 solar cell
50 photoelectric conversion part
1 crystal semiconductor substrate
60 light receiving surface electrode
70 back surface electrode
61, 71 finger electrode
62, 72 bus bar electrode
76 to 79 metal film
81 to 84 wiring member
91 light-receiving-surface protective member
92 back-surface protective member
95 encapsulant
98 light reflection member

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

What is claimed is:

1. A solar cell module, comprising:
a solar cell string comprising a plurality of solar cells;
a light-receiving-surface protective member disposed on a light receiving surface side of the solar cell string;
a back-surface protective member disposed on a back surface side of the solar cell string; and
a plurality of metal films,
wherein the light-receiving-surface protective member is light transmissive,
wherein the plurality of solar cells are arranged apart from each other and are interconnected via one or more wiring members,
wherein each of the solar cells comprises: a photoelectric conversion part; a patterned light-receiving-surface metal electrode provided on a light receiving surface of the photoelectric conversion part; and a patterned back-surface metal electrode provided on a back surface of the photoelectric conversion part,
wherein each of the metal films is provided between the photoelectric conversion part of the solar cell and the back-surface protective member, forming a cell exposed region on a peripheral edge of a back surface of the solar cell, and
wherein the cell exposed region is a region where the metal film is not provided and includes at least a part of the back-surface metal electrode.

2. The solar cell module according to claim 1, wherein the metal film is in contact with the photoelectric conversion part.

3. The solar cell module according to claim 1, wherein an area of the cell exposed region is 0.05 to 0.5 times an area of a region provided with the metal film.

4. The solar cell module according to claim 1, wherein the back-surface protective member is light reflective.

5. The solar cell module according to claim 1, further comprising a light reflection member, wherein the light reflection member is provided in a region where the solar cell is not disposed.

6. The solar cell module according to claim 5, wherein the light reflection member has an uneven structure on a surface on the light receiving surface side.

7. The solar cell module according to claim 6, wherein the light reflection member has a convex portion that extends in parallel with a side of an adjacent solar cell.

8. The solar cell module according to claim 1, further comprising a light-receiving-surface encapsulant and a back-surface encapsulant,
wherein the light-receiving-surface encapsulant is disposed between the solar cell string and the light-receiving-surface protective member,
wherein the back-surface encapsulant is disposed between the solar cell string and the back-surface protective member, and
wherein a thickness of the back-surface encapsulant is larger than a thickness of the light-receiving-surface encapsulant.
